(19) United States
(12) Patent Application Publication
(10) Pub. No.: US 2009/0235952 A1
(43) Pub. Date: Sep. 24, 2009

(54) DEVICE AND METHOD FOR WET TREATING PLATE-LIKE SUBSTRATES

(75) Inventors: Alexander Lippert, Villach (AT); Alexander Pfeuffer, Heiligenstadt (DE)

Correspondence Address: YOUNG & THOMPSON, 209 Madison Street, Suite 500, ALEXANDRIA, VA, 22314, US

(73) Assignee: SEZ AG, Villach (AT)

(21) Appl. No.: 12/299,647

(22) PCT Filed: Apr. 18, 2007
(86) PCT No.: PCT/EP07/53768

§ 371 Date: Nov. 5, 2008

(30) Foreign Application Priority Data
May 5, 2006 (AT) A 784/2006

(51) Int. Cl. B08B 3/12; H01L 21/00

(52) U.S. Cl. 134/1; 134/182; 134/183; 134/154; 134/33; 134/34

(57) ABSTRACT

Disclosed is a device for wet treatment of plate-like articles including:

a first plate

holding elements for holding a single plate-like article substantially parallel to the first plate,

first dispensing elements for introducing liquid into a first gap between said first plate and a plate-like article when being treated,

wherein the first plate is a silicon plate, which consists at least 99 wt % of silicon, the silicon plate being in contact with the treatment liquid, when the plate-like article is treated. Further disclosed is a method associated therewith.

The invention relates to a device for wet treatment of plate-like articles comprising a plate, holding means for holding a single plate-like article substantially parallel to the plate, and dispensing means for introducing liquid into a first gap between said first plate and a plate-like article when being treated. If in the following the term wafer is used such plate-like articles are meant.

Such plate-like articles can be disc-like articles such as semiconductor wafers, or compact discs as well as polygonal articles such as flat panel displays.

With the above-mentioned device the gap between the plate-like article and the plate, which is parallel to the plate-like article is filled with liquid during wet treatment. The liquid shall be removed from the plate-like article without leaving any liquid residues (droplets) on the plate-like article's surface facing the plate. With inert coating materials on the plate, such as PTFE (e.g. Teflon), the problem occurs that fine droplets remain on the plate, and thereafter are transferred from the plate surface to the plate-like article's surface. Such droplets, which have been transferred from the plate to the plate-like article's surface, typically form undesired marks. If such marks origin from aqueous solutions they are called watermarks.

If the plate-like article shall be treated with ultrasonic energy metal plates are often used to couple the sound into the gap between the plate-like article and the plate. As metal contacts mostly have to be avoided as a contact with the treatment liquid such plates are covered with an inert coating (e.g. PTFE). Whenever herein the term ultrasonic is used it shall be understood that megasonic is included herein as being a specific form of ultrasonic i.e. above 1 MHz.

An object of the invention is to improve process conditions in the above-mentioned device.

The invention meets the objects by providing a device for wet treatment of plate-like articles comprising:
a first plate
holding means for holding a single plate-like article substantially parallel to said first plate,
first dispensing means for introducing liquid into a first gap between said first plate and a plate-like article when being treated,
   wherein the first plate is a silicon plate, which consists of at least 99 wt % of silicon. The silicon plate is in contact with the treatment liquid, when the plate-like article is treated.

The first plate (silicon plate) should have a size so that it can cover at least 25% of the plate-like article to be treated. If for instance a 300 mm silicon wafer shall be treated the silicon plate used as the first plate may be a 150 mm silicon wafer. Although any silicon plate can be used as the first plate it is preferred to use a silicon wafer used in semiconductor industry. If the whole area of the plate-like article shall be covered when a semiconductor wafer shall be treated preferably a silicon wafer of the same size or bigger shall be used. For cost saving purposes a reclaimed wafer can be used as the first plate. A reclaimed wafer is a wafer, which has been produced for the semiconductor industry however does not fulfill the exact specification for producing ICs anymore.

The gap between the plate-like article and the first plate preferably has a thickness of 0.1 mm to 20 mm.

An advantage—when using silicon as the material for the first plate—is that silicon is highly inert to most of the chemical treatment liquids and does not emit any undesired substances—it neither emits particles nor any metals. Especially if silicon wafers shall be cleaned it is favorable that the plate being parallel to the to-be-cleaned surface behaves similar to the surface of the plate. Even if the cleaning liquid etches silicon it is acceptable to use a silicon plate. With currently used etching cleaning liquids (diluted liquids) not more than 10 nm are etched per treated object. Consequently 20,000 objects can be treated if a loss of thickness of the silicon plate (first plate) of 0.2 mm is acceptable. Considered that 30 wafers per hour can be treated with such a device and that such a device is used for 8,000 hours a year the silicon plate has to be replaced once a month.

In a preferred embodiment the device further comprises at least one ultrasonic transducer acoustically coupled to at least the silicon plate. To use the silicon plate for coupling ultrasonic energy into the gap between said first plate and a plate-like article when being treated it can be avoided to use metal transducer plates or the silicon plate is used to separate the metal transducer plate (coated or uncoated) from the gap.

Another embodiment further comprises rotating means for rotating said holding means and said first plate relative to each other about an axis substantially perpendicular to said first plate. This is preferably carried out by providing rotating means to rotate the plate-like article.

Preferably the silicon plate is made of single crystalline silicon because poly crystalline silicon is chemically less inert because it is easier attackable by chemicals on its grain boundaries.

In yet another embodiment the first dispensing means comprises at least one liquid supply opening, which is formed in the silicon plate. This gives the advantage that the liquid, which is supplied to the first gap can be more evenly distributed into the gap.

When using ultrasonic transducers the device may be equipped with a resonator plate, which is coupled to the ultrasonic transducer, wherein the first dispensing means comprises at least one liquid supply opening, which is formed in the silicon plate and wherein the resonator plate is parallel arranged to the silicon plate thereby forming a second gap between the resonator plate and the silicon plate, and the second gap is a part of the treatment liquid supply path.

Such a liquid supply opening can be mechanically drilled into the silicon plate or etched. Etching can be performed with techniques well known in semiconductor industries e.g. atmospheric downstream plasma etching or wet etching (e.g. with an etchant comprising nitric acid and hydrofluoric acid). The opening can be specifically covered with a specially etch or erosion resistant material to avoid significant changes of the opening diameter during the lifetime of the plate.

An alternative device has a silicon plate wherein no opening is formed in the silicon plate. To fill the gap a cross flow has to be generated. In other words liquid is introduced from one edge region of the plate into the gap and drained from the opposite side.

If the device further comprises a second liquid supply means for supplying liquid onto the side of the plate-like article not facing the first plate both sides of the plate-like article can be simultaneously treated. If ultrasonic energy is transmitted through the silicon plate and the plate-like article has similar thickness and similar impedance as the silicon plate ultrasonic energy is transmitted to the side of the plate-like article, which does not face the silicon plate and thus both sides can be simultaneously treated with ultrasonic energy.

The device may further comprise a second plate, which is substantially parallel to said first plate, whereby the second liquid supply means introduce liquid into a gap between the second plate and the plate-like article when being treated.

If ultrasonic transducers are used the ultrasonic transducer can be directly attached to the silicon plate or the ultrasonic transducer is indirectly coupled to the silicon plate through a coupling medium, selected from the group consisting of solids and liquids.

When such coupling medium is a coupling liquid it is preferred that the coupling liquid has a specific impedance Z differing less than 5% to the specific impedance of the treatment liquid. The specific impedance Z is a product of specific sound velocity and specific density.

In yet another embodiment when using an ultrasonic transducer such ultrasonic transducer is coupled to the silicon plate so that the ultrasonic transducer and the silicon plate enclose an angle in a range of 5° to 50°.

Another aspect of the invention is a method for wet treatment of plate-like articles comprising:
holding a single plate-like article,
bringing a first plate substantially parallel to said plate-like article
introducing liquid into a first gap between said first plate and a plate-like article when being treated,
   wherein the first plate is a silicon plate, which consists at least 99 wt % of silicon, the silicon plate being in contact with the treatment liquid.

In a preferred embodiment of the method ultrasonic energy is applied to the plate-like article through the silicon plate.

In another embodiment of the method the plate-like article and said first plate are rotated relative to each other about an axis substantially perpendicular to said first plate.

Further details and advantages of the invention can be realized from the detailed description of a preferred embodiment.

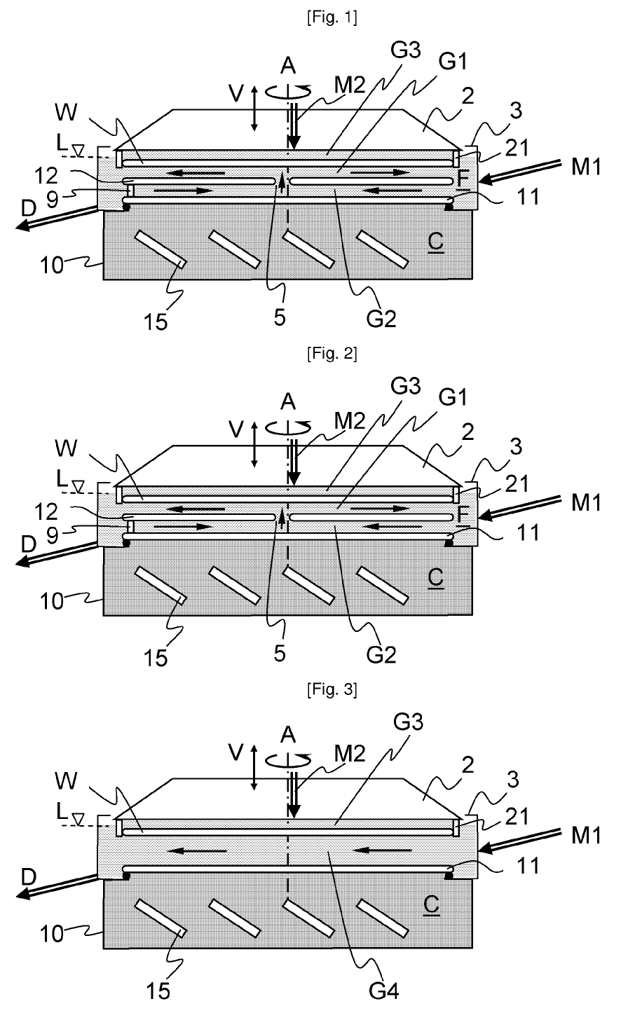

FIG. 1 shows a schematic cross sectional view of a first embodiment of the invention during wet treating a wafer.

FIG. 2 shows a schematic cross sectional view of a second embodiment of the invention during wet treating a wafer.

FIG. 3 shows a schematic cross sectional view of a third embodiment of the invention during wet treating a wafer.

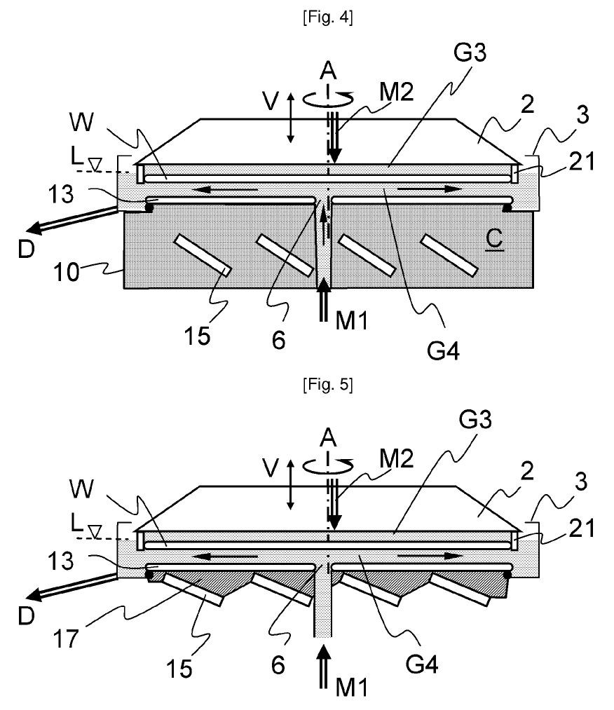

FIG. 4 shows a schematic cross sectional view of a fourth embodiment of the invention during wet treating a wafer.

FIG. 5 shows a schematic cross sectional view of a fifth embodiment of the invention during wet treating a wafer.

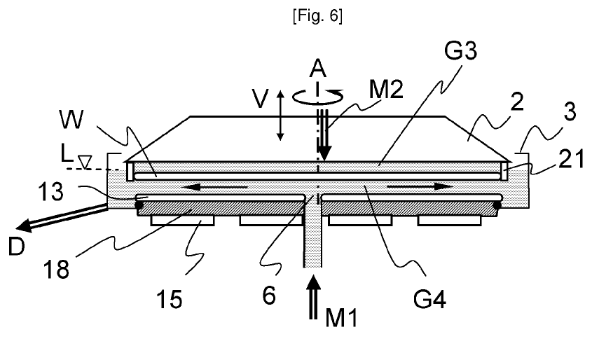

FIG. 6 shows a schematic cross sectional view of a sixth embodiment of the invention during wet treating a wafer.

The first embodiment shown in FIG. 1 comprises an ultrasonic tank 10 holding a coupling liquid C and a treatment tank 3 for holding treatment liquid F when a plate-like article W is treated. The treatment tank 3 is acoustically coupled to the ultrasonic tank 10 through a resonator plate 11 made of 0.7 mm thick single crystalline silicon, which is the cover plate of the ultrasonic tank 10. The resonator plate 11 is sealed against the ultrasonic tank 10 to avoid mixing of coupling liquid and treatment liquid F. The resonator plate 11 thereby forms the bottom plate of the treatment tank 3. The resonator plate 11 is clamped against the ultrasonic tank 10 with a clamping ring (not shown) e.g. made of PVDF. The coupling liquid C is fed into the ultrasonic tank and drained from the ultrasonic tank 10 through not shown pipes. Such piping system can be used to maintain the coupling liquid's temperature constant.

Within the ultrasonic tank a plurality of ultrasonic transducers 15 are mounted at an angle of 35° with respect to the resonator plate 11. The preferred angle can be calculated from thickness of the silicon plate and its acoustical properties, frequency of the ultrasonic waves and the acoustical properties of the preferred treatment liquid and the coupling liquid so that the resonator plate becomes transparent for the ultrasonic waves (see A. Tomozawa “The Visual Observation and the Simulation of Ultrasonic Transmission through Silicon in Mega-sonic Single Wafer Cleaning System” presented at Hawaii conference of the Electrochemical Society (ECS) in 1999).

In a distance of about 5 mm a liquid guiding plate 12 is arranged parallel to the resonator plate 11, which forms the gap G2. The liquid guiding plate 12 and the resonator plate 11 are fixed together by pin-shaped support members 9. Preferably at least three support members are arranged circumferentially between the liquid guiding plate 12 and the resonator plate 11. The liquid guiding plate 12 is made of the same material (silicon) and the same thickness as the resonator plate 11. The liquid guiding plate 12 has a central hole 5 with a diameter of 10 mm. The hole 5 may be set off the center by preferably half the diameter of the hole.

A chuck 2 with holding members 21 for securely holding a plate-like article is vertical movably mounted to the treatment tank 10 such that a plate-like article W can be immersed in the treatment liquid F, and such that the plate-like article W can be held substantially parallel to the liquid guiding plate 12 in a close distance to form a gap G1 of 0.1 to 5 mm between the plate-like article W and the liquid guiding plate 12. The chuck 2 is designed as a spin-chuck so that it can be slowly rotated (5-60 RPM) during ultrasonic treatment and can be spun at high velocity (up to 3000 RPM and more) for drying purposes.

Treatment liquid can be introduced into the treatment tank through a first media supply M1 and drained from the treatment tank through a drain D located on the opposite part of the sidewall of the treatment tank 3.

Additionally treatment liquid can be introduced into the gap G3 between the spin-chuck and the plate-like article W through a second media supply M2.

A method of treating a silicon wafer W is described as follows. The spin-chuck 2 is lifted by to receive a wafer W, which is gripped by the holding members 21 and thereby forming a gap G3 of about 2 mm. After the chuck is lowered so that a gap G1 of 2 mm is formed between the wafer W and the liquid guiding plate 12 cleaning liquid is introduced through the first and the second media supply M1 and M2. The wafer W thereby is slowly rotated at a velocity of 5 RPM. Thereby the gaps G3 and G2 are filled. The cleaning liquid flows in G2 from the edge to the center as indicated by arrows and is supplied to the downward facing side of the wafer W through the hole 5 in the liquid guiding plate 12. Thereafter the liquid fills the gap G1 and flows from the center to the edge of the wafer W. The liquid in gap G1 is accelerated by the rotating wafer similar to a centrifugal pump.

When the liquid level L reaches a maximum value liquid is permanently drained through drain D. Liquid flow through media supplies M1 and M2 is than controlled to have a mean liquid level at a selected value. After all three gaps G1, G2, G3 have been filled with liquid ultrasonic is switched on and the wafer W is treated for a certain time (e.g. 10 s-5 min) and at a certain spin speed (e.g. 20 RPM). Ultrasonic energy which is transmitted through the resonator plate 11 is then further transmitted through the liquid guiding plate 12. If thickness and material of the resonator plate 11 and the liquid guiding plate 12 are the same there is almost no loss of wave energy when ultrasonic waves pass the liquid guiding plate 12. Thereafter the cleaning liquid is displaced with rinsing liquid (DI-water), which is thereafter displaced by drying liquid and/or drying gas through the media supplies M1 and M2. In order to support the drying process spin speed can be accelerated up to e.g. 1000 RPM.

The second embodiment of the invention shown in FIG. 2 is based on the first embodiment but with the following deviations. The liquid guiding plate 12 is connected to the cylindrical sidewall of the treatment tank 3 by a concentric separating ring 14. The separating ring 14 is inwardly sealed to the outer edge of the liquid guiding plate 12 and outwardly sealed to the side wall of the tank 3. The liquid guiding plate 12 and the separating ring 14 together separate the tank 3 into an upper part and a lower part. The first media supply M1 is connected to the lower part of the treatment tank 3 and upper part is connected to the drain.

Medium (liquid or gas), which is introduced through the first medium supply M1 thus is forced to flow through the central hole 5 of the liquid guiding plate even if the wafer W is not rotating. With this embodiment the liquid level L does not have to be controlled because the drain D can be selected big enough so that all liquid introduced from media supplies M1 and/or M2 can be easily drained.

The third embodiment of the invention shown in FIG. 3 is based on the first embodiment but with the following deviations. An intermediate liquid guiding plate is omitted. Thus there is only one single gap G4 between the plate-like article W and the resonator plate 11.

Treatment liquid can be introduced into the treatment tank through a first media supply M1 and drained from the treatment tank through a drain D located on the opposite part of the sidewall of the treatment tank 3. Thus liquid flows in the gap G4 across the plate-like article W from one side of the edge to the opposite side of the edge. Ultrasonic energy is introduced to the treatment liquid through the silicon resonator plate 11 and applied to the plate-like article's surface.

The fourth embodiment of the invention shown in FIG. 4 is based on the third embodiment; however, the liquid, which is supplied from the first media supply is introduced through a central opening 6 in the resonator plate 13. Liquid thus flows from the center to the edge of the plate-like article W. With this embodiment liquid level control is not necessary.

The fifth embodiment of the invention shown in FIG. 5 is based on the fourth embodiment; however, transducers 15 are not coupled to the resonator plate 13 via a coupling liquid C but are bonded to a coupling plate 17. The coupling plate carries on the one side the transducers 15 and is bonded to the silicon resonator plate 13 on the other side. The coupling plate 17 is specifically formed so that transducers 15 and resonator plate 13 enclose an angle of 25°. The coupling plate is made of metal (e.g. aluminum, stainless steel), glass, oxide ceramic (e.g. aluminum oxide), non-oxide ceramic (e.g. silicon carbide), or crystal (e.g. sapphire, quartz).

The sixth embodiment of the invention shown in FIG. 6 is based on the fifth embodiment; however, the coupling plate 18 is formed so that transducers 15 are arranged parallel to the resonator plate 13. Alternatively the coupling plate 18 can be omitted and the transducers are bonded directly onto the silicon resonator plate. Suitable adhesives for bonding transducers to a coupling plate or to a silicon resonator plate are organic resins (e.g. epoxy resins) or sinterable or vitrifiable inorganic materials (e.g. glass).

1. Device for wet treatment of plate-like articles comprising
1.1 a first plate
1.2 holding means for holding a single plate-like article substantially parallel to said first plate,
1.3 first dispensing means for introducing liquid into a first gap between said first plate and a plate-like article when being treated,
wherein the first plate is a silicon plate, which consists of at least 99 wt % of silicon, the silicon plate being in contact with the treatment liquid, when the plate-like article is treated.

2. Device according to claim 1 further comprising at least one ultrasonic transducer acoustically coupled to at least the silicon plate.

3. Device according to claim 1 further comprising rotating means for rotating said holding means and said first plate relative to each other about an axis substantially perpendicular to said first plate.

4. Device according to claim 1 wherein the silicon plate is made of single crystalline silicon.

5. Device according to claim 1 wherein the first dispensing means comprises at least one liquid supply opening, which is formed in the silicon plate.

6. Device according to claim 2 with a resonator plate, which is coupled to the ultrasonic transducer, wherein the first dispensing means comprises at least one liquid supply opening, which is formed in the silicon plate and wherein the resonator plate is parallel arranged to the silicon plate thereby forming a second gap between the resonator plate and the silicon plate, and the second gap is a part of the treatment liquid supply path.

7. Device according to claim 1 wherein no opening is formed in the silicon plate.

8. Device according to claim 1 further comprising a second liquid supply means for supplying liquid onto the side of the plate-like article not facing the first plate.

9. Device according to claim 8 further comprising a second plate, which is substantially parallel to said first plate, whereby the second liquid supply means introduces liquid into a gap between the second plate and the plate-like article when being treated.

10. Device according to claim 2 wherein the ultrasonic transducer is directly attached to the silicon plate.

11. Device according to claim 2 wherein the ultrasonic transducer is indirectly coupled to the silicon plate through a coupling medium, selected from the group consisting of solids and liquids.

12. Device according to claim 11 wherein the coupling medium is a coupling liquid.

13. Device according to claim 11 wherein the coupling liquid has a specific impedance Z differing less than 5% to the specific impedance of the treatment liquid.

14. Device according to claim 2 wherein the ultrasonic transducer is coupled to the silicon plate so that the ultrasonic transducer and the silicon plate enclose an angle in a range of 5° to 50°.

15. Method for wet treatment of plate-like articles comprising:
15.1 holding a single plate-like article,
15.2 bringing a first plate substantially parallel to said plate-like article
15.3 introducing liquid into a first gap between said first plate and a plate-like article when being treated,
wherein the first plate is a silicon plate, which consists of at least 99 wt % of silicon, the silicon plate being in contact with the treatment liquid.

16. Method according to claim 15 wherein ultrasonic energy is applied to the plate-like article through the silicon plate.

17. Method according to claim 15 wherein the plate-like article and said first plate are rotated relative to each other about an axis substantially perpendicular to said first plate.
